(19) United States
(12) Patent Application Publication
(10) Pub. No.: US 2006/0091561 A1
(43) Pub. Date: May 4, 2006

(54) Electronic component comprising external surface contacts and a method for producing the same

(76) Inventors: Jochen Dangelmaier, Beratzhausen (DE); Harry Hedler, Germering (DE); Roland Irsigler, Munchen (DE); Stefan Paulus, Zeitlarn (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 10/515,613

(22) PCT Filed: May 23, 2003
(86) PCT No.: PCT/DE03/01683

§ 371 Date: Sep. 13, 2005

(30) Foreign Application Priority Data
May 29, 2002 (DE) 10224124.4

(51) Int. Cl. H01L 23/48; H01L 21/48

(52) U.S. Cl. 257/778; 438/108; 257/787; 438/124; 257/737; 257/693

(57) ABSTRACT

The invention relates to an electronic device and a method for producing it having external area contacts and having a rewiring structure and also having a semiconductor chip, which has contact areas, the external area contacts being electrically connected to the contact areas at least by means of the rewiring structure, and the external area contacts and/or the rewiring structure having chemically or galvanically selectively deposited metal.

### FIELD OF THE INVENTION

The invention relates to an electronic device having external area contacts and having a rewiring structure and also having a semiconductor chip, and to a method for producing the same, in accordance with the generic type of the independent claims.

### BACKGROUND

Electronic devices having external area contacts and having a rewiring structure that rewires the microscopically small contact areas of a semiconductor chip to macroscopically large external area contacts have, as carriers of the rewiring structure, additional complex rewiring plates or rewiring sheets with correspondingly incorporated through contacts or with bonding channels provided. In this context, microscopically small is understood to mean an order of magnitude which can only be measured with a light microscope, while macroscopically large structures can perfectly well be discerned by the naked eye. In this context, a rewiring structure is understood to mean the metallic structure per se, which may have contact pads of the order of magnitude of the contact areas of the semiconductor chip, rewiring lines in the micrometer and/or submicron range and external contact areas of the order of magnitude of the external area contacts.

Consequently, electronic devices of this type have not only a rewiring structure but also a rewiring carrier that has a rewiring structure as rewiring body and is cast into the plastic housing composition. The metal layers on the rewiring carrier from which the rewiring structure is constructed may have rolling textures if the rewiring carriers have insulation plates or insulation sheets laminated with rolled sheets. They may have a coarsely crystalline structure if the metal layers are injected or vapor-deposited onto the rewiring carrier or applied sintering-metallographically or are produced by means of a dipping process. Consequently, a wide variety of crystallographic metal structures arise for the rewiring layers and are characteristic of the metals deposited as rewiring structure.

In any event, a rewiring structure for an electronic device is associated with the fact that an additional rewiring body having the rewiring structure has to be concomitantly accommodated in the plastic housing of the electronic device, which is associated with an additional space requirement for the electronic device and complex production methods for a rewiring body.

The document DE 100 04 410 A1 discloses a semiconductor component having external area contacts situated at the underside and also a method for the production thereof, the external area contacts having chemically or galvanically selectively deposited metal. The known method is suitable for the production of external area contacts and has the disadvantage that a rewiring body cannot be produced, and the electronic device has the disadvantage that it has no rewiring structure whatsoever.

### SUMMARY

It is an object of the invention to reduce the space requirement of an electronic device having a rewiring structure and to provide an electronic device which, in terms of its construction, does not have a rewiring carrier for a rewiring structure and is cost-effective to produce.

This object is achieved by means of the subject matter of the independent claims. Advantageous developments of the invention emerge from the dependent claims.

In one embodiment the invention specifies an electronic device having external area contacts and having a rewiring structure and having a semiconductor chip, which has contact areas. In this electronic device according to the invention, the external area contacts are electrically connected to the contact areas of the semiconductor chip at least by means of the rewiring structure. In this case, the semiconductor chip and the rewiring structure are embedded in a plastic housing composition, while the external area contacts are freely accessible on the underside of the electronic device. Furthermore, the external area contacts and the rewiring structure have chemically or galvanically selectively deposited metal.

An electronic device of this type has the advantage that the space requirement for fitting a rewiring structure is minimized by virtue of the fact that no rewiring carrier whatsoever is to be provided for the rewiring structure, rather this function is undertaken by the plastic housing composition directly as a result of the embedding of the rewiring structure in the plastic housing composition. Moreover, the electronic device has the advantage that the metal material of the rewiring structure has a chemically or galvanically selectively deposited metal which is distinguished by its fine crystallinity and moreover, opens up the possibility of realizing extremely finely patterned rewiring structures in part in the submicron range insofar as the rewiring lines of the rewiring structure are concerned.

The size of the bonding fingers or contact pads required for connecting the rewiring structure to the contact areas of the semiconductor chip is dependent on the size or the order of magnitude of the contact areas and also the connecting technology between the contact areas of the semiconductor chip and contact pads of the rewiring structure. While internal area contacts of the order of magnitude of a few square micrometers can be realized in the case of a flip-chip connecting technology, in the case of bonding technology the miniaturization of the contact areas of the semiconductor chip and the contact pads of the rewiring structure is determined by the bonding wire diameter and, consequently, cannot be arbitrarily minimized since the bonding wires have diameters of between 15 and 50 micrometers.

The semiconductor chip may be mounted on the rewiring structure by means of flip-chip technology, the contact areas of the semiconductor chip being electrically connected to contact pads of the rewiring structure by means of internal area contacts. As already mentioned above, said internal area contacts may have a size of a few square micrometers, so that the flip-chip technology with internal area contacts may have an extremely dense contact structure and it is thus possible to realize an extremely fine grid dimension for spacing apart the contact pads.

In another embodiment, a semiconductor chip may be mounted on the rewiring structure using flip-chip technology, the contact areas of the semiconductor chip being connected to contact pads of the rewiring structure by means of internal contact balls. A technology of this type, working with contact balls or contact bumps made of solder material, has structures that require a connecting area of tens of square micrometers between the contact area of the semiconductor chip and the contact pads of the rewiring structure.

Consequently, the user can choose from three different orders of magnitude, the largest area requirement occurring in the case of bonding connections between contact areas of the semiconductor chip and contact pads of the rewiring structure, which require hundreds of square micrometers owing to the bonding wires.

Contact balls or contact bumps that are an order of magnitude smaller than bonding connections can be used for the connection between contact areas and contact pads, and, finally, electrical connections that are a further order of magnitude smaller can be realized using a flip-chip technology with internal area contacts. In the case of all three orders of magnitude for the connection between contact areas and contact pads, the electronic device has the advantage that there is a considerable space saving since the rewiring structure does not require an additional rewiring carrier.

If the electronic device is equipped with a semiconductor chip using bonding technology, then its rear side may be mounted on the rewiring structure by means of an insulating adhesive layer. The contact areas on the active top side of the semiconductor chip are connected to contact pads of the rewiring structure in the vicinity of the semiconductor chip by means of bonding wires, in which case, on account of the construction of the electronic device according to the invention, the area contacts may be arranged beneath the region of the semiconductor chip, so that, with this embodiment of the invention, area contacts may be distributed over the entire underside of the electronic device, and the rewiring structure enables a so-called “fan-in” arrangement for the external area contacts despite bonding connection technology.

The electronic device may additionally have through contacts which are chemically or galvanically selectively deposited on the rewiring structure and which connect the underside of the electronic device with the external area contacts to the opposite top side of the electronic device. This provision of chemically or galvanically selectively deposited through contacts enables a plurality of individual electronic devices to be stacked to form a stacked module with continuous electrical connection from the topmost device of the stack through to the bottommost device of the stack. For this purpose, the through contacts are embedded in the plastic housing composition and surround the respective semiconductor chip.

In a further embodiment of the invention, the chemically or galvanically deposited metal may have nickel or a nickel alloy. This has the advantage that, for the deposition of such a nickel alloy produced chemically or galvanically, it is possible to use a carrier material made of copper or iron alloys that can be etched away for the chemical or galvanic deposition, so that it is possible to effect etching removal of the carrier material for the rewiring structure and the external area contacts since the etching process can be stopped at the interface with nickel by means of a reduced etching rate. Identical advantages are also afforded by chemically or galvanically deposited metals made of silver or silver alloys, and made of gold or gold alloys. A carrier made of copper or an iron alloy that can be removed by etching may be used in each of these cases. Palladium or a palladium alloy may also be used chemically or galvanically on a preformed etchable carrier for forming the rewiring structure and the external area contacts.

A further embodiment of the invention provides for the chemically or galvanically deposited metal to have a layer sequence comprising gold nickel gold, so that only a thin layer is composed of the noble metal, while the main body of the rewiring structure and the external area contacts have the less expensive metal. In a similar form, it is possible to construct a layer sequence comprising palladium nickel palladium and, finally, it is also possible to use layer sequences comprising palladium copper palladium or gold copper gold, but in those cases the noble metal layers made of gold or palladium have to be made thick enough to possibly withstand the etching attack on the copper or the iron of the carrier material.

Completely independent of the etchability of different metals for the carrier material and for the structures of the electronic device that are to be deposited is the possibility of using an electrically conductive sheet or a sheet coated with a metal layer as carrier. In both cases, such a carrier material on which the external area contacts and the rewiring structure of the electronic device are deposited galvanically affords the advantage that the sheet can be stripped away from the electronic device after completion of the latter without necessitating an etching step.

A method for producing an electronic device having external area contacts and having a rewiring structure, the external area contacts and the rewiring structure having chemically or galvanically selectively deposited metal, may be effected by means of the following method steps.

Firstly, cutouts are produced in an electrically conductive carrier in a predetermined grid dimension for a chemical or galvanate deposition of the external area contacts of the electronic device. For this purpose, different materials are used for the external area contacts and for the top side of the carrier.

A patterned photoresist layer is applied to such a carrier whilst leaving free the cutouts for the external area contacts and for regions in which the rewiring structure is to be chemically or galvanically deposited. There then follows a method step in which the material for the area contacts and for the rewiring structure is chemically or galvanically deposited on the carrier in the uncovered areas of the photoresist layer. After the deposition has ended, the patterned and insulating photoresist layer can be removed. Consequently, the electrically conductive carrier now has external area contacts in its cutouts and a rewiring structure that has been patterned by the photoresist layer.

A semiconductor chip is then applied to this rewiring structure whilst connecting the contact areas of the semiconductor chip to contact pads of the rewiring structure. The semiconductor chip and the rewiring structure are subsequently embedded in a plastic housing composition. Afterward, the carrier is separated from the encapsulated device whilst uncovering the external area contacts. Finally, in order to protect the rewiring structure that is uncovered on the other side of the electronic device, a soldering resist layer may be applied on the device side, having the area contacts, whilst leaving free the external area contacts.

A method of this type has the advantage that it is thereby possible to realize electronic devices which do not exist in this compactness with a functional rewiring structure and also cannot be produced by the previously known means for producing a rewiring structure. Rather, here, new paths are taken in order to introduce a rewiring structure without an additional carrier directly into the plastic housing composition, with the result that the rewiring carrier that is otherwise necessary can be obviated.

Even the often complex production of through contacts through the rewiring carrier can be surmounted by the method according to the invention. Moreover, the method can be employed both for flip-chip mounted semiconductor chips and for semiconductor chips connected by means of bonding wires. In the case of flip-chip connected semiconductor chips, the rewiring structure may be provided in order to obtain a so-called “fan-out” effect, in which, in a microscopically fine grid dimension, contact areas of a semiconductor chip are to be distributed over a larger area having a macroscopic grid dimension by means of a corresponding rewiring structure, and, on the other hand, for semiconductor chips connected by means of bonding wires, it is possible to obtain a “fan-in” effect, in which, on the area beneath the semiconductor chip, it is possible to arrange external area contacts for more intensive utilization of the device underside.

A further advantage of the present invention is that it is possible to prepare a carrier of this type for a plurality or even a multiplicity of electronic devices, a multiplicity of electronic devices arising simultaneously or in parallel on said carrier by using the same steps as for an individual electronic device. It is only after the removal or separation of the carrier from the plastic housing composition that the plastic housing composition can then be divided into individual electronic devices. Such an exemplary implementation of the method can considerably reduce the costs for the production of electronic devices, particularly if the loss carrier is provided in wafer form, because in this case tried and tested semiconductor wafer technologies may preferably be used for producing the rewiring structures.

The introduction of cutouts in a predetermined grid dimension into a metallic carrier may be effected in two different methods. On the one hand, the cutouts may be introduced by embossing technology and, on the other hand, the cutouts may be introduced by means of an etching technology. While embossing technology involves preparing corresponding embossing tools that introduce the cutouts extremely precisely into a copper plate, for example, a very fine patterning of the external area contacts may be achieved in the case of the etching technology by the carrier material firstly being covered with a patterned photoresist layer and then the cutouts being etched out of the carrier plate in the regions in which there is no photoresist layer present. With both method variants, a carrier material is finally available which can be provided with external area contacts extremely precisely in subsequent steps.

A further method variant envisages firstly providing a first photoresist layer for the deposition of area contact material in the cutouts in a first deposition step, said first photoresist layer leaving free the regions of the external area contacts. After the deposition of the area contacts, the first photoresist layer is removed and a second patterned photoresist layer is applied, which leaves free those surface regions which are to be provided with a rewiring structure. Afterward, these regions may be filled galvanically or chemically with a metal in a second deposition step, and the second patterned photoresist layer may subsequently be removed.

Consequently, the carrier material finally has a rewiring structure and an underlying structure comprising external area contacts which are arranged in a predetermined grid dimension. The advantage of this second method variant is that the deposition process for the external area contacts is separate from the deposition process for the rewiring structure, so that it is possible to realize considerably thicker area contacts compared with the thickness of the rewiring structure.

In a further implementation of the method according to the invention, an electrically conductive sheet is used as carrier, into which sheet are embossed cutouts for forming area contacts of the electronic device. An electrically conductive sheet of this type may be stripped away from the plastic housing material after completion of the electronic devices and thus facilitates the production of a multiplicity of electronic devices since no carrier material has to be etched away from the underside of the electronic devices. Instead of an electrically conductive carrier material such as a conductive sheet, a nonconductive carrier material on which a conductive layer is deposited may also be used for the carrier. Said conductive layer may be a metal layer or a layer made of graphite.

If a carrier made of a sheet is used for the method, then for the step of embedding the device in a plastic housing composition, the carrier made of a sheet is mechanically supported by an adapted mold. In contrast to the mechanically stable carrier made of metals such as copper or iron with cutouts, this procedure has the advantage that the mold can be used multiply and only the sheet constitutes consumable material, it being possible for such sheets to be produced significantly less expensively than a mechanically stable carrier made of metal.

A further embodiment of the invention envisages providing additional cutouts for external area contacts of through contacts on the carrier. In order to deposit through contacts of this type, a further patterned photoresist layer is applied, after completion and deposition of the area contacts and of the rewiring structure, on the carrier with a thickness greater than the thickness of the semiconductor chip provided for the electronic device. The patterned photoresist layer leaves free the external area contacts that are present for the deposition of the through contacts. For this purpose, in this region the further photoresist layer has openings that are subsequently filled chemically or galvanically to form through contacts.

Afterward, this further photoresist layer adapted to the thickness of the semiconductor chip may be removed, so that now external area contacts, a rewiring structure and additional through contacts that extend from the underside of the electronic device as far as the top side of the electronic device are completed on the carrier. A semiconductor chip may be fitted into a structure prepared in this way, and be electrically connected, by means of known technology such as flip-chip technology or bonding technology.

One possibility for embedding the components then present in a plastic housing composition may be effected by means of a mold for an injection molding technology, the mold having cavities adapted to the external housing form of the plastic housing composition. Another possibility for applying a plastic housing composition consists in employing a dispensing method in which the plastic housing composition is sprayed on.

For simultaneous production of a multiplicity of electronic devices, a carrier in wafer form is provided, which is firstly provided with cutouts, afterward, all of the method steps being carried out jointly for production of a multiplicity of electronic devices and finally, after removal of the carrier in wafer form, the multiplicity of electronic devices that are packaged in a plastic housing composition being separated by division of the plastic housing composition to form a multiplicity of individual electronic devices. A method of this type has the advantage that, for simultaneous or parallel production, it is possible to use production lines previously developed for the treatment and processing of semiconductor wafers. The housing technology thus becomes compatible with method steps that are already known in wafer technology, which reduces development and production costs.

To summarize, it shall be emphasized that the apparatus according to the invention and the method according to the invention enhance the possibility of configuration of existing packaging systems for semiconductor chips and at the same time reduce the space requirement for an electronic device having a semiconductor chip. Furthermore, the costs for producing electronic devices of this type are reduced by virtue of the fact that a complex rewiring body is dispensable. For this purpose, it is possible instead to form a removable copper plate with additional cutouts in order to form the external area contacts, said cutouts being implemented by an embossing process during the production of the copper plate or by a single-sided etching prior to the application of area contacts and rewiring structures.

The provision of two photoresist steps for the production of the area contacts and the rewiring structure makes it possible to realize different material thicknesses of the external area contacts and of the rewiring structure, so that it is possible to realize rewiring structures in the range of thickness of from 5 to 50 micrometers, and on the other hand, external area contacts having a thickness of from 10 to 500 micrometers.

For the production of stackable devices, it is possible to provide smaller cutouts for the external area contacts of the through contacts and larger cutouts for the external area contacts in order, for example, to arrange macroscopic solder bumps or solder balls on the external area contacts, and through contacts having diameters of the order of magnitude of bonding wires on the area contacts. What is achieved in this case with the smaller area contacts for the through contacts is that the space requirement for the electronic device is reduced.

In order to be able to deposit vertical through contacts, it is possible to use a special photoresist and a special technology for producing the photoresist layer, so that, during the exposure and during the development of the photoresist layer, vertical sidewalls of the openings in the photoresist layer for the through contacts arise. In addition to the chemical or galvanic deposition of metals for the through contacts, the openings for the through contacts may be filled with soldering material having a high melting point as well, which is distributed uniformly in the openings for the through contacts in a flow process. The through contacts may subsequently also be cleaned from the top side and also be provided with an additional noble metal layer.

The electronic device according to the invention is extremely robust. All contacts are embedded in corresponding resin components of the plastic housing composition thereby minimizing the risk of damage to the rewiring structure or the through contacts during a test and handling phase. Moreover, the overall device height is extremely small as a result of the rewiring carrier being obviated, so that typically it is possible to realize devices having a device height of less than 400 micrometers as a result of which doubly stacked devices having a height of less than 900 micrometers become possible.

The invention will now be discussed in greater detail on the basis of embodiments with reference to the accompanying figures.

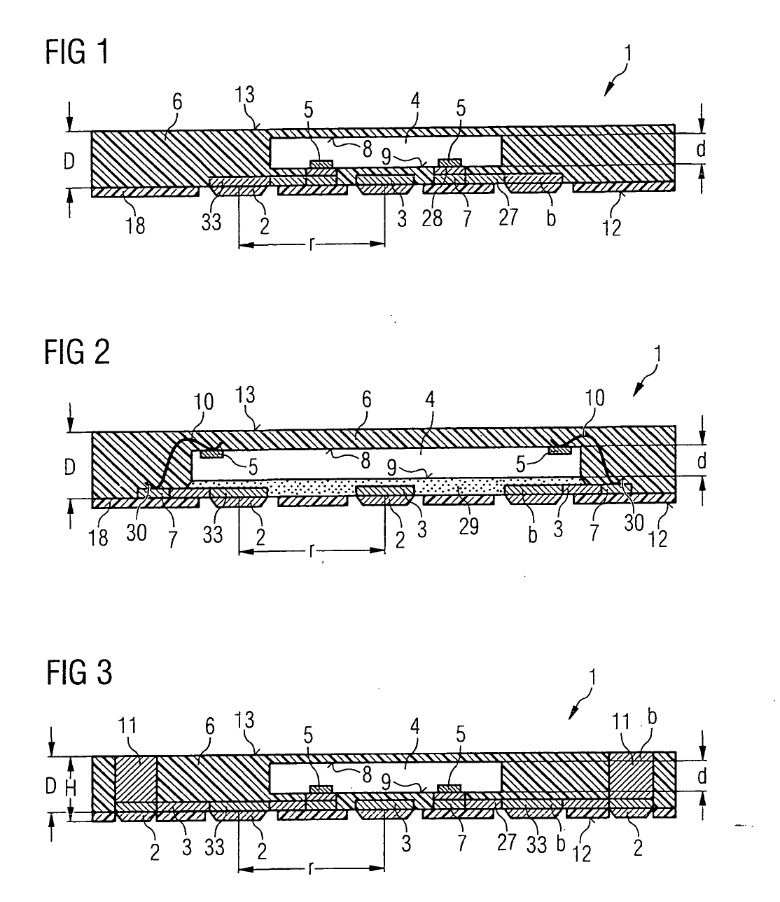

FIG. 1 illustrates a diagrammatic cross-sectional view of an electronic device of a first embodiment of the invention.

FIG. 2 illustrates a diagrammatic cross-sectional view of an electronic device of a second embodiment of the invention.

FIG. 3 illustrates a diagrammatic cross-sectional view of an electronic device of a third embodiment of the invention.

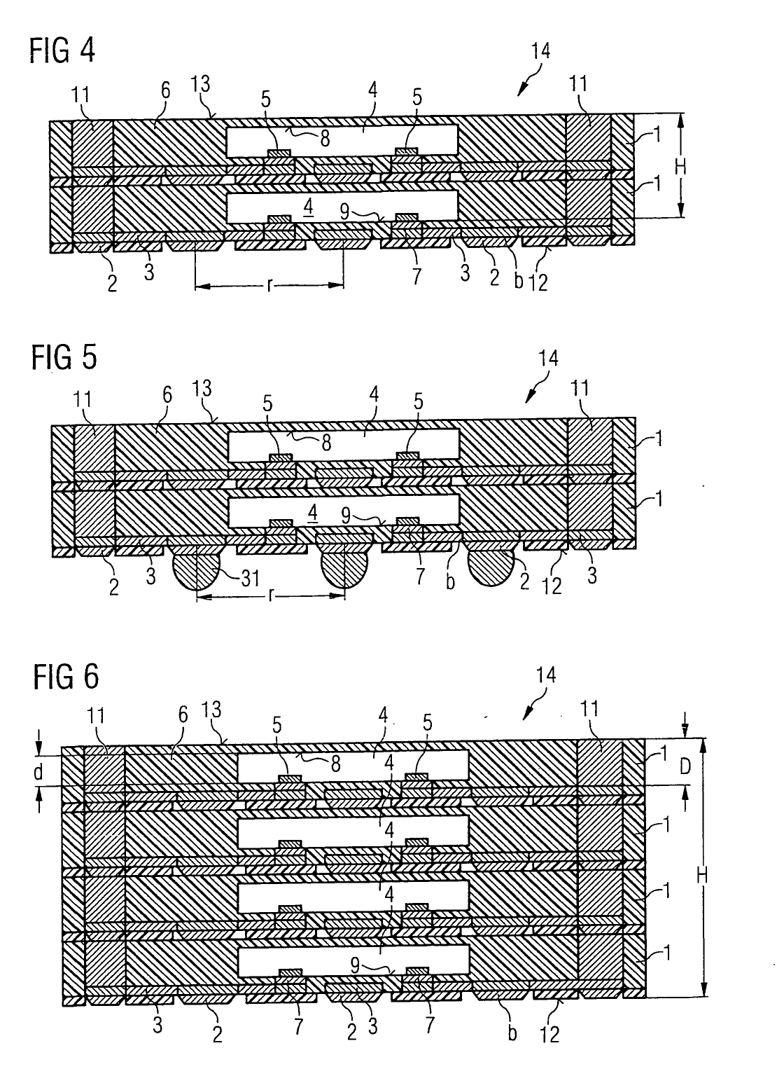

FIG. 4 illustrates a diagrammatic cross-sectional view of a first stack comprising two electronic devices of the third embodiment of the invention.

FIG. 5 illustrates a diagrammatic cross-sectional view of a second stack comprising two electronic devices of the third embodiment of the invention.

FIG. 6 illustrates a diagrammatic cross-sectional view of a third stack comprising four electronic devices of the third embodiment of the invention.

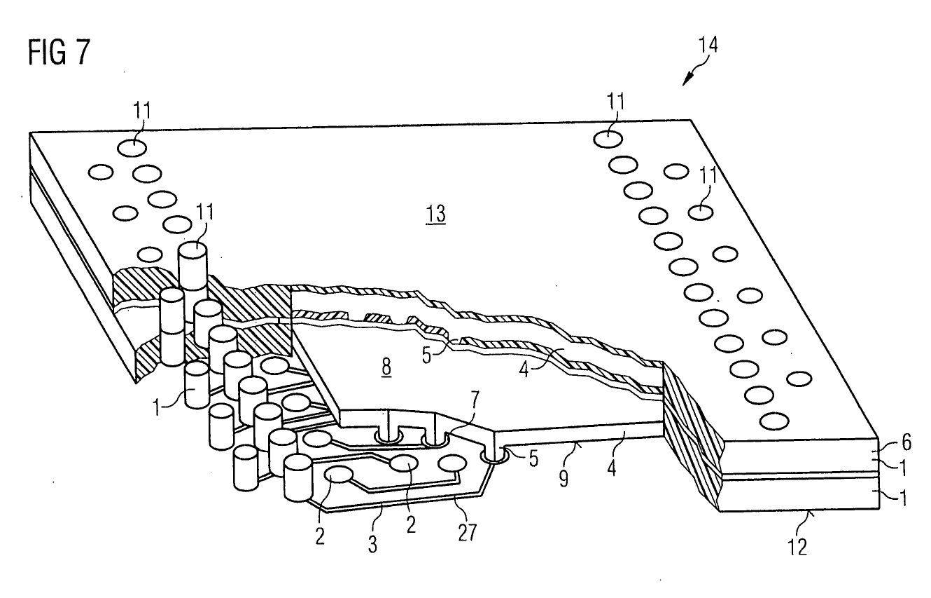

FIG. 7 illustrates a partly cut-away perspective view of a fourth stack comprising two electronic devices of a further embodiment of the invention.

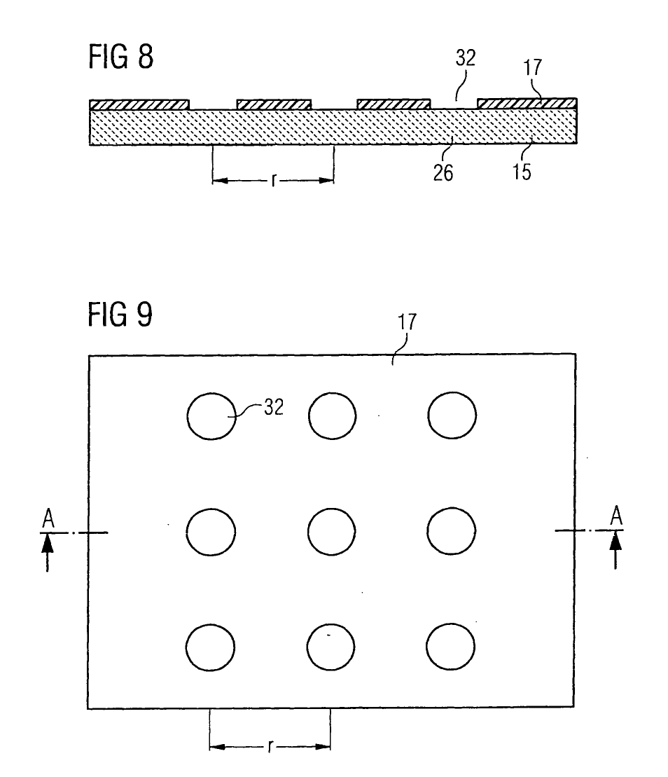

FIGS. 8 to 23 illustrate schematic diagrams for the production of an electronic device by means of a first implementation of the method according to the invention.

FIG. 8 illustrates a diagrammatic cross-sectional view of a carrier plate with a patterned photoresist layer.

FIG. 9 illustrates a diagrammatic plan view of a carrier plate with a patterned photoresist layer.

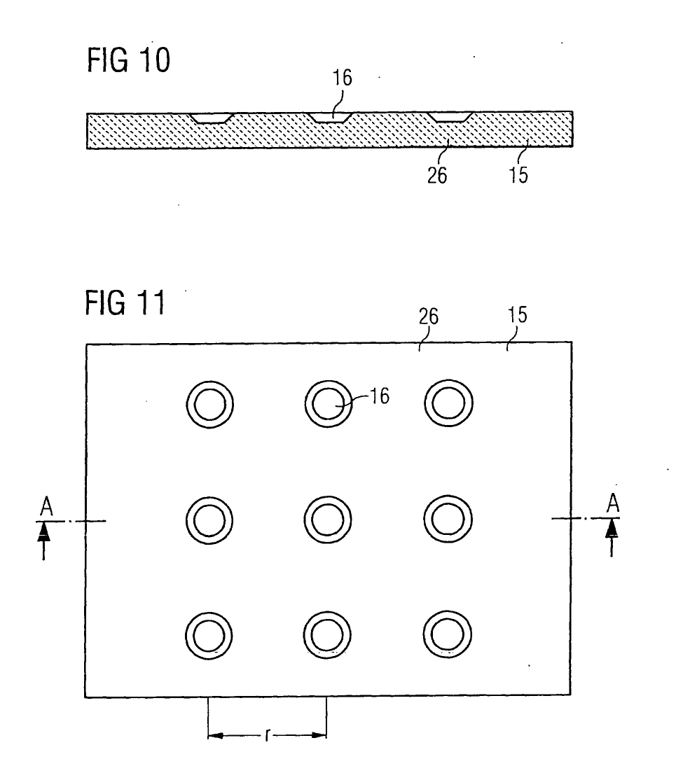

FIG. 10 illustrates a diagrammatic cross-sectional view of a carrier plate with etched cutouts for external area contacts.

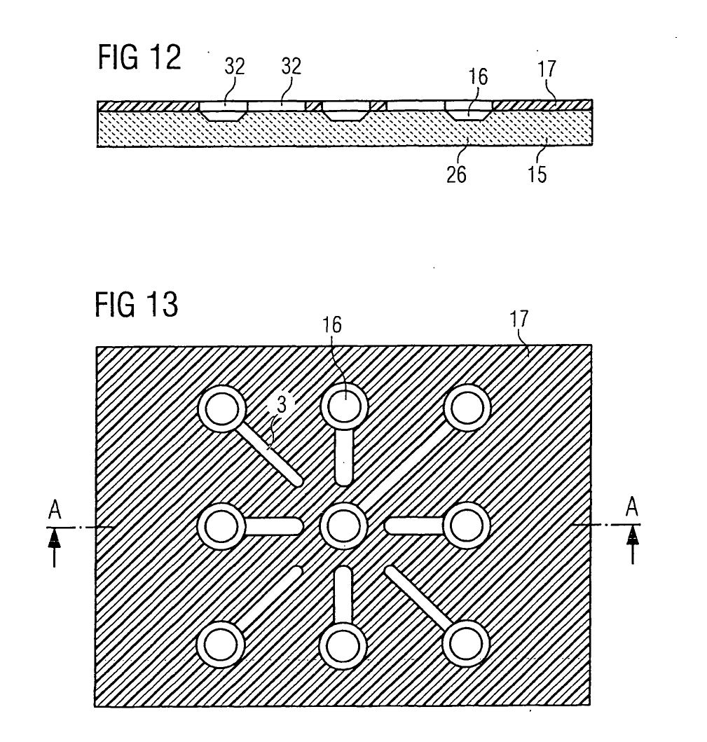

FIG. 11 illustrates a diagrammatic plan view of a carrier plate with etched cutouts for external area contacts.

FIG. 12 illustrates a diagrammatic cross-sectional view of a carrier plate with a patterned photoresist layer for selective deposition of a rewiring structure and for deposition of external area contacts.

FIG. 13 illustrates a diagrammatic plan view of a carrier plate with a patterned photoresist layer for selective deposition of a rewiring structure and for selective deposition of external area contacts.

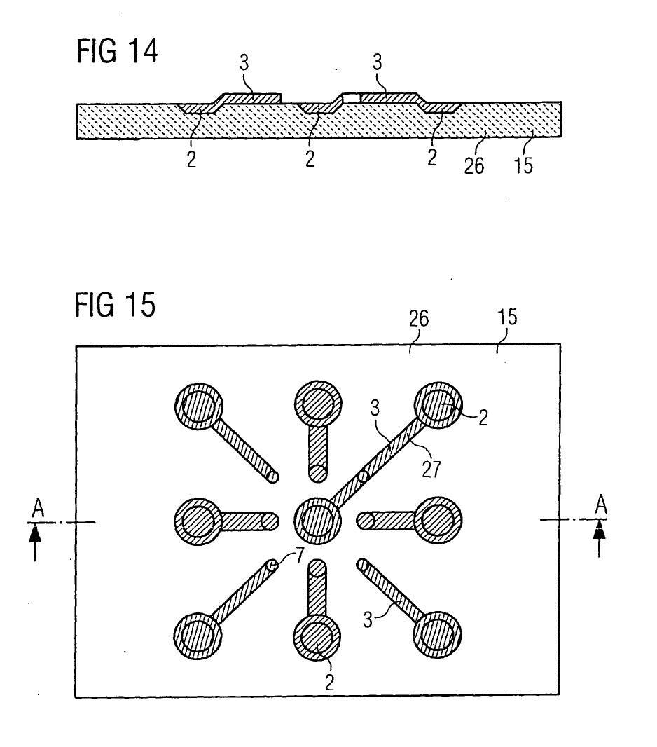

FIG. 14 illustrates a diagrammatic cross-sectional view of a carrier plate with a galvanically deposited rewiring structure and with galvanically simultaneously deposited external area contacts.

FIG. 15 illustrates a diagrammatic plan view of a carrier plate with a rewiring structure deposited on the carrier plate and of external area contacts.

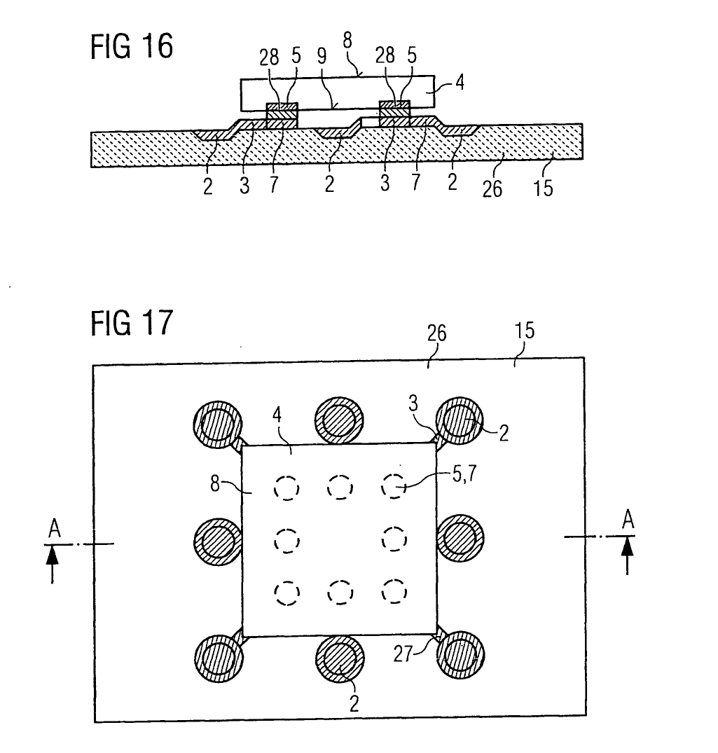

FIG. 16 illustrates a diagrammatic cross-sectional view of a carrier plate with an applied semiconductor chip.

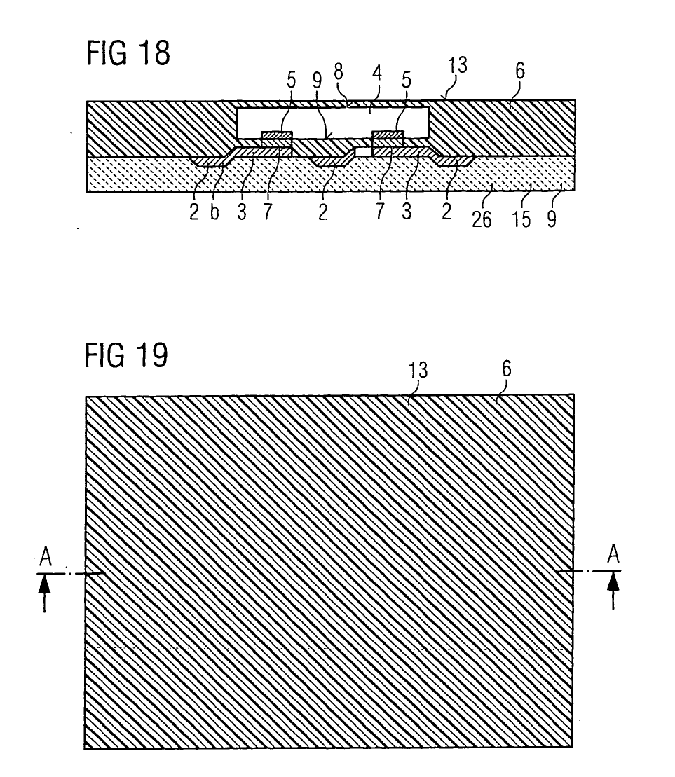

FIG. 17 illustrates a diagrammatic plan view of a carrier plate with an applied semiconductor chip.

FIG. 18 illustrates a diagrammatic cross-sectional view of a carrier plate provided with plastic housing composition.

FIG. 19 illustrates a diagrammatic plan view of a carrier plate provided with plastic housing composition.

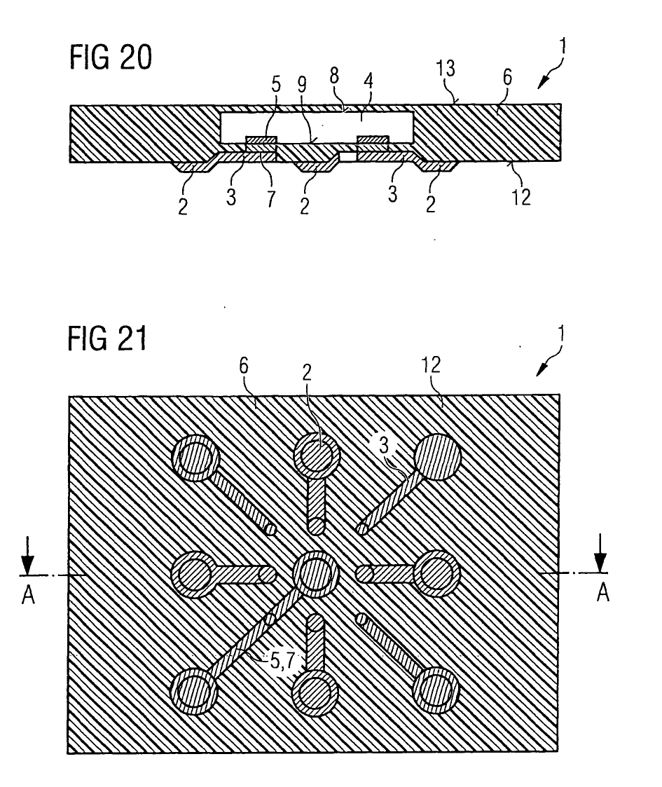

FIG. 20 illustrates a diagrammatic cross-sectional view of an electronic device after the removal of the carrier from the device.

FIG. 21 illustrates a diagrammatic bottom view of an electronic device after the removal of the carrier from the device.

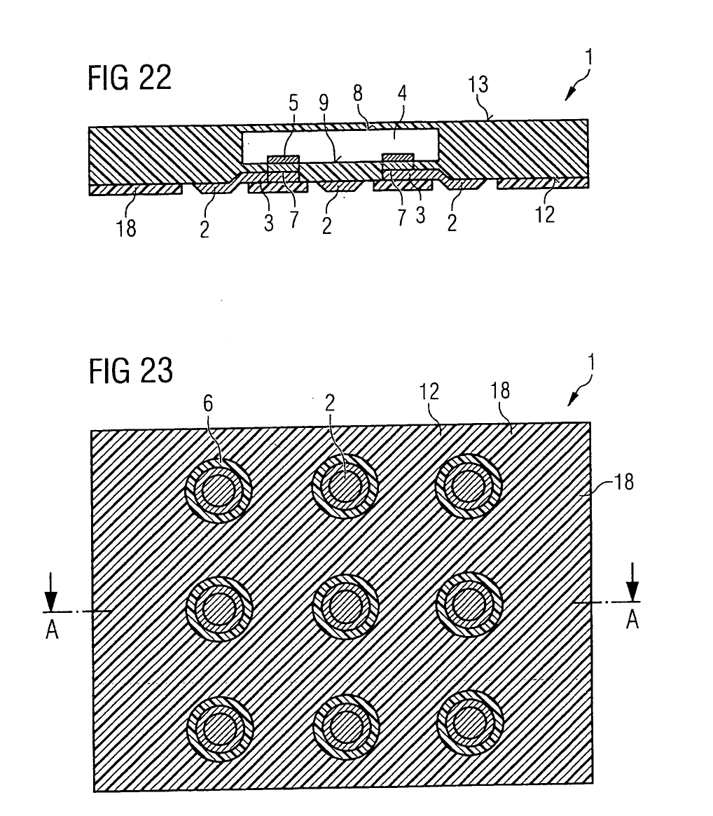

FIG. 22 illustrates a diagrammatic cross-sectional view of an electronic device after the application of a soldering resist layer.

FIG. 23 illustrates a diagrammatic bottom view of an electronic device after the application of a soldering resist layer,

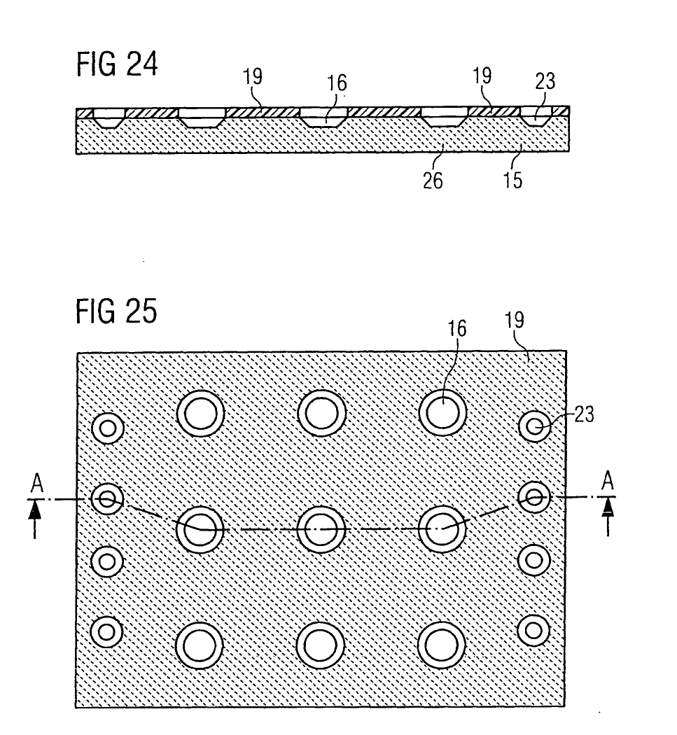

FIGS. 24 to 39 illustrate schematic diagrams for the production of an electronic device by means of a third exemplary implementation of the method according to the invention.

FIG. 24 illustrates a diagrammatic cross-sectional view of a carrier plate with a patterned first photoresist layer for the selective deposition of external area contacts.

FIG. 25 illustrates a diagrammatic plan view of a carrier plate with a patterned photoresist layer for the selective deposition of external area contacts.

FIG. 26 illustrates a diagrammatic cross-sectional view of a carrier plate with galvanically deposited external area contacts.

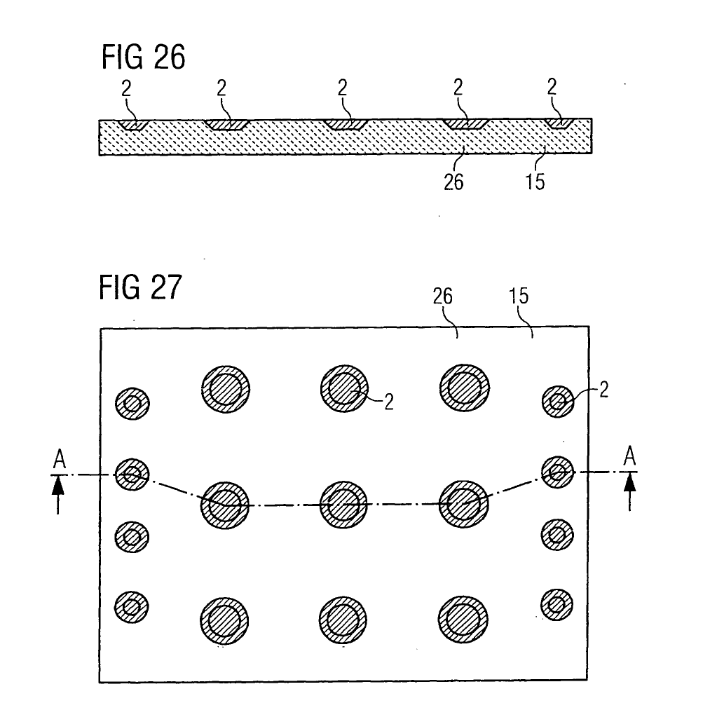

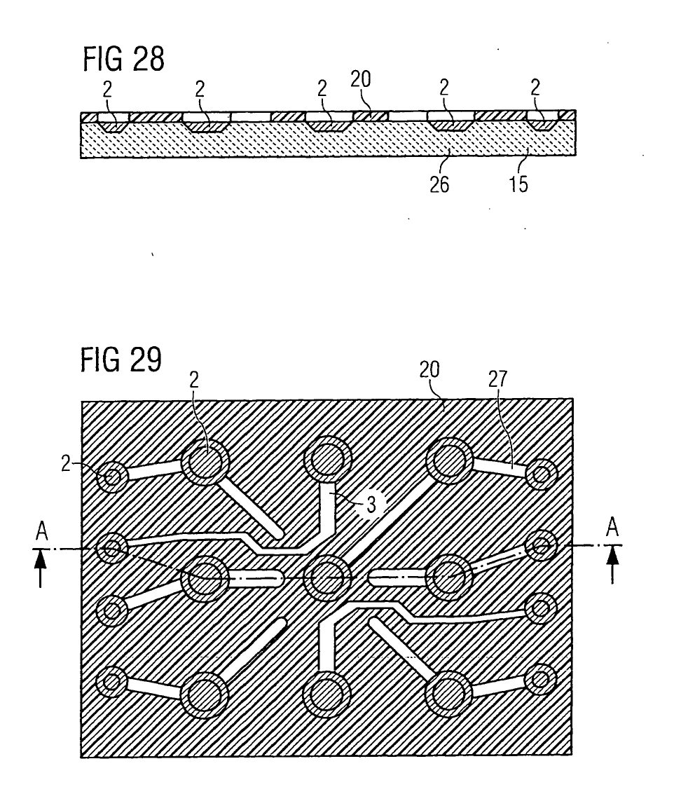

FIG. 27 illustrates a diagrammatic plan view of a carrier plate with external area contacts deposited on the carrier plate.

FIG. 28 illustrates a diagrammatic cross-sectional view of a carrier plate with a patterned second photoresist layer for the selective deposition of a rewiring structure.

FIG. 29 illustrates a diagrammatic plan view of a carrier plate with a second photoresist layer for the selective deposition of a rewiring structure.

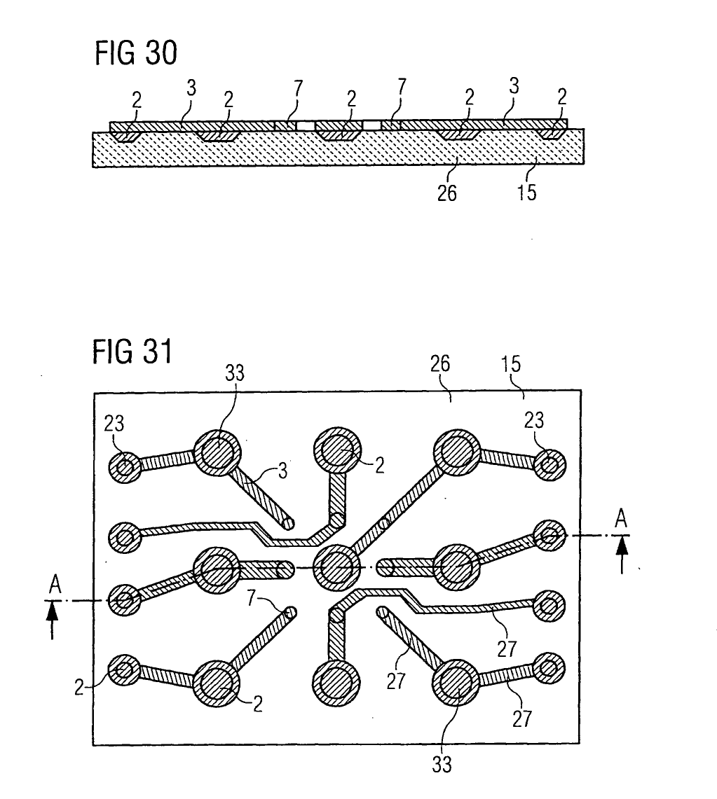

FIG. 30 illustrates a diagrammatic cross-sectional view of a carrier plate with galvanically deposited rewiring structure.

FIG. 31 illustrates a diagrammatic plan view of a carrier plate with a rewiring structure deposited on the carrier plate.

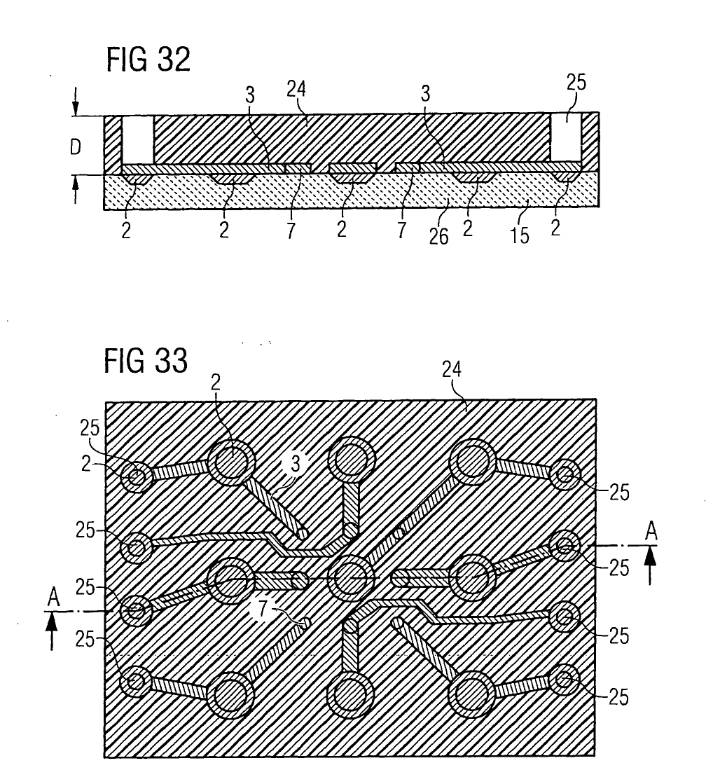

FIG. 32 illustrates a diagrammatic cross-sectional view of a carrier plate with a further patterned photoresist layer for the selective deposition of through contacts.

FIG. 33 illustrates a diagrammatic plan view of a carrier plate with a further patterned photoresist layer for the selective deposition of through contacts.

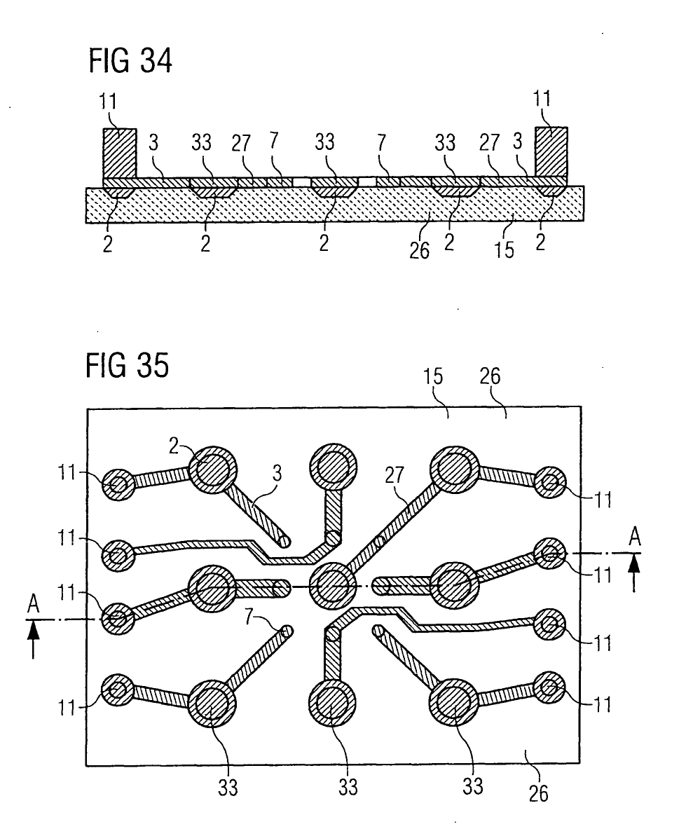

FIG. 34 illustrates a diagrammatic cross-sectional view of a carrier plate with galvanically deposited through contacts after the removal of the photoresist layer.

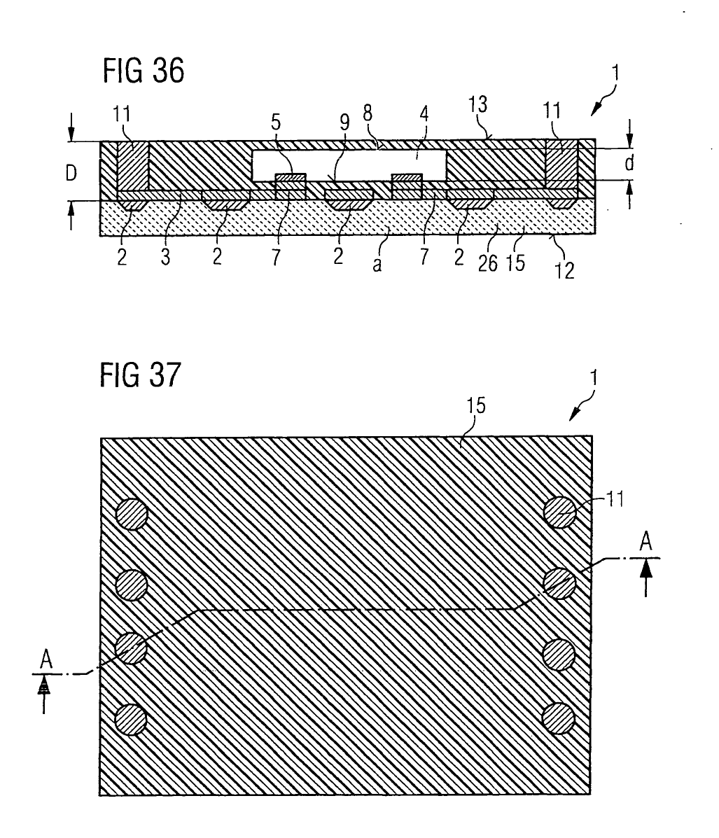

FIG. 35 illustrates a diagrammatic plan view of a carrier plate with through contacts deposited on the carrier plate after the removal of the photoresist layer.

FIG. 36 illustrates a diagrammatic cross-sectional view of a carrier plate provided with plastic housing composition.

FIG. 37 illustrates a diagrammatic plan view of a carrier plate provided with a plastic housing composition.

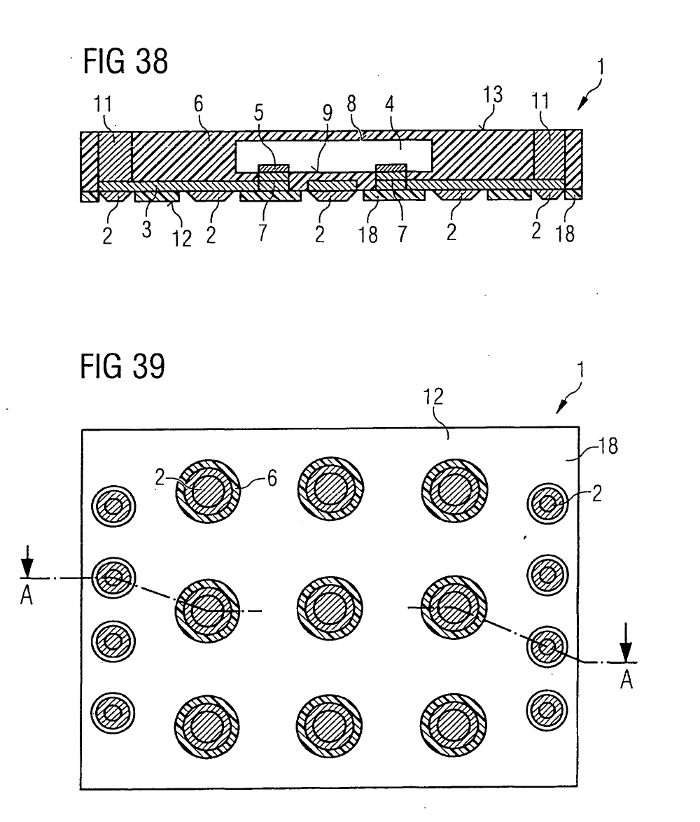

FIG. 38 illustrates a diagrammatic cross-sectional view of an electronic device after the application of a soldering resist layer.

FIG. 39 illustrates a diagrammatic bottom view of an electronic device after the application of a soldering resist layer.

### DETAILED DESCRIPTION

FIG. 1 illustrates a diagrammatic cross-sectional view of an electronic device of a first embodiment of the invention. Reference symbol 2 denotes area contacts of the electronic device 1. The reference symbol 3 denotes a rewiring structure, which, like the area contacts, has a chemically or galvanically deposited metal. The reference symbol 4 denotes a semiconductor chip having an active top side 9 and a passive rear side 8. The reference symbol 5 denotes contact areas on the active top side 9 of the semiconductor chip 4. The reference symbol 7 denotes contact pads of the rewiring structure, which can be adapted to the positions of the contact areas 5 of the semiconductor chip 4. The reference symbol 12 denotes the underside of the electronic device, on which the area contacts 2 are arranged in a grid dimension r. The reference symbol d denotes the thickness of the semiconductor chip 4, which is smaller than the thickness D of the plastic housing composition 6.

This electronic device 1 does not have a rewiring carrier despite rewiring, structure 3, with the aid of which the microscopically small contact areas 5 of the semiconductor chip 4 are led to macroscopically large external area contacts 2 by means of rewiring lines 27. Rather, the function of the rewiring carrier or rewiring body is performed by the plastic housing composition 6, with the result that the space requirement of the electronic device 1 can be minimized.

In this first embodiment of the invention, the semiconductor chip 4 is arranged in the plastic housing composition on the rewiring structure 3, having a chemically or galvanically selectively deposited metal, using flip-chip technology. The microscopically small contact areas 5 are connected, with the aid of the rewiring structure 3, in part to external area contacts 2 which are arranged beyond the edge of the semiconductor chip 4 in the plastic housing composition 6. This arrangement is also called a “fan-out” arrangement. It is advantageously employed in this embodiment of the invention in order to accommodate a sufficient number of macroscopic area contacts 2 on the underside 12 of the electronic device 1.

The connection between the contact areas 5 of the semiconductor chip 4 and the contact pads 7 of the rewiring structure 3 is produced by means of internal area contacts 28. Such internal area contacts 28 have a size of only a few square micrometers, while the external area contacts 2 may have a size of tens to hundreds of square micrometers. Instead of internal area contacts 28, as in the embodiment according to FIG. 1, internal contact balls or contact bumps may also produce the connection between the contact areas 5 of the semiconductor chip 4 and the contact pads 7 of the rewiring structure 3. However, such internal contact bumps or contact balls increase the thickness D of the plastic housing composition 6 by almost 50 micrometers since internal contact balls or contact bumps are made significantly thicker than the microscopically small internal area contacts 28, which can be produced in thicknesses of a few micrometers.

In order to protect the underside 12 of the electronic device 1, the device 1 may have a soldering resist layer 18 on the underside 12, which covers the underside of the rewiring structure 3 and leaves free only the external area contacts 2.

The external area contacts 2 may also have chemically or galvanically deposited metal and may have the same material as the rewiring structure 3. As chemically or galvanically deposited metals, use is made of nickel, palladium, gold or silver or a layer sequence of these metals is provided. Alloys of these metals may also be employed. For layer sequences of these metals, layer sequences comprising gold nickel gold, palladium nickel palladium, gold silver gold have proved successful, in which case the intermediate layer may also have copper if the outer layers have a thickness that withstands any etching attack of a copper etchant. However, this requirement need only be met when, during the production of such an electronic device, a sacrificial cathode made of copper is used for the galvanic deposition of the area contacts and the rewiring structure.

Chemically or galvanically deposited external area contacts 2 and rewiring structures 3 made of copper may be realized whenever these structures are deposited on a correspondingly pre-embossed sheet that either has a conductive coating or is itself conductive. Copper has the advantage, particularly for the rewiring structure 3, that rewiring lines 27 can be produced with a line width in the submicron range.

FIG. 2 illustrates a diagrammatic cross-sectional view of an electronic device 1 of a second embodiment of the invention. Components having functions identical to those in FIG. 1 are identified by the same reference symbols and are not discussed separately.

A difference between the second embodiment of the invention according to FIG. 2 and the first embodiment of the invention according to FIG. 1 consists in the fact that the semiconductor chip is not arranged in the plastic housing composition 6 using flip-chip technology, but rather is mounted by its rear side 8 on the rewiring structure 3 by means of an insulating adhesive layer 29. The contact areas 5 arranged on the active top side 9 of the semiconductor chip 4 are connected by means of bonding wires 10 to the contact pads 7, here formed as bonding fingers 30, to the rewiring structure and thus to the external area contacts 2. The order of magnitude of the bonding fingers 30 and also of the contact areas 5 depends on the diameter of the bonding wires 10 and is of the order of magnitude of tens of micrometers, preferably between 15 and 50 micrometers.

While the bonding fingers 30 are arranged outside the semiconductor chip 4 in the plastic housing composition 6, the external area contacts 2 may be arranged beneath the semiconductor chip 4, which is also referred to as a “fan-in” arrangement. Although a metallic chip island is not provided below the semiconductor chip 4 in this second embodiment of the invention, it is possible, through a centrally arranged external area contact 2 via the rewiring structure 3 and a corresponding bonding connection 10, to place a ground connection to the active top side of the semiconductor chip 4, which can perform the function of the ground feed of a chip island.

FIG. 3 illustrates a diagrammatic cross-sectional view of an electronic device of a third embodiment of the invention. Components having functions identical to those in the previous figures are identified by the same reference symbols and are not discussed separately.

The third embodiment of the invention according to FIG. 3 differs from the previous embodiments of the invention by virtue of the fact that through contacts 11 are arranged on the rewiring structure, said through contacts extending from the underside 12 of the electronic device 1 to the top side 13 of the electronic device 1. The material b of the through contacts 11 may likewise have a chemically or galvanically deposited metal or may be produced by means of molten solder.

The external area contact 2 associated with the through contact 11 may have, at its underside, a coating that facilitates soldering of the through contact 11 to other through contacts 11. The same may be embodied on the top side 13 for the through contact 11. Both the external area contact 2 and the through contact 11 may have significantly smaller diameters than the macroscopic external area contacts 2 for the connection to the contact areas 5 of the semiconductor chip 4. It is thus possible to arrange area contacts 11 all around the semiconductor chip 4, which do not significantly increase the space requirement of the plastic housing composition 6.

The total thickness H of such an electronic device may be less than 400 micrometers, preferably in the range of 250 to 300 micrometers. Such a small height of the electronic device 1 is achieved in particular by the flip-chip mounting of the semiconductor chip 4 and by the use of internal area contacts 28 for the connection between the contact areas 5 of the semiconductor chip 4 and the contact pads 7 of the rewiring structure 3.

FIG. 4 illustrates a diagrammatic cross-sectional view of a first stack comprising two electronic devices 1 of the third embodiment of the invention. Components having functions identical to those in the previous figures are identified by the same reference symbols and are not discussed separately.

The provision of through contacts 11 in the plastic housing composition 6 makes it possible, as shown by the fourth embodiment of the invention, for such electronic devices 1 of the third embodiment of the invention as are shown in FIG. 3 to be stacked vertically on top of one another to form a module 14. In the course of this stacking process, only the through contacts 11 with the external area contacts 2 of the through contacts 11 are interconnected, so that the two semiconductor chips 4 can communicate with one another via the rewiring structure 3. The grid dimension r of the external area contacts 2 is preserved in this case.

Such a stack comprising two electronic devices 1 of the third embodiment of the invention, as shown in FIG. 4, can be realized with a total height H of less than 900 micrometers; the total height H preferably lies between 500 and 600 micrometers. The height H can be reduced further by thinning the semiconductor chips 4 by grinding. In any event, the thickness of the rewiring carrier is saved in the case of this stack compared with stacks having rewiring plates or rewiring bodies since, in the case of this embodiment of the invention, only rewiring structures made of a chemically or galvanically deposited metal are realized and supporting rewiring carriers are not necessary.

FIG. 5 illustrates a diagrammatic cross-sectional view of a second stack comprising two electronic devices 1 of the third embodiment of the invention. Components having functions identical to those in the previous figures are identified by the same reference symbols and are not discussed separately.

The stack represented here in FIG. 5 differs from the stack in FIG. 4 by virtue of the fact that solder balls 31 or solder bumps are arranged on the area contacts 2 of the lower electronic device 1 and facilitate a connection of the electronic module 14 comprising a plurality of electronic devices 1 to a superordinate circuit structure, for example on a printed circuit board.

FIG. 6 illustrates a diagrammatic cross-sectional view of a third stack comprising four electronic devices 1 of the third embodiment of the invention. Components having functions identical to those in the previous figures are identified by the same reference symbols and are not discussed separately.

The total height H of this module 14 comprising vertically stacked electronic devices 1 is less than 1.8 millimeters, preferably between 1000 and 1200 micrometers, and total thicknesses of 250 micrometers may be achieved using semiconductor chips 4 ground thin. In the total height H, at least quadruple the thickness of a rewiring carrier in the form of a rewiring plate is saved in the case of this embodiment of the invention, with the result that extremely compact electronic modules 14 can be produced.

FIG. 7 illustrates a partly cut-away perspective view of a fourth stack comprising two electronic devices I of a further embodiment of the invention. Components having functions identical to those in the previous figures are identified by the same reference symbols and are not discussed separately.

This exemplary embodiment illustrates the height flexibility and compactness of stacks comprising electronic devices 1 of the third embodiment of the invention. The number of through contacts 11 is thirty-six in the case of this embodiment of the invention. It is correspondingly necessary to provide thirty-six rewiring lines 27 in the individual device planes. Given this high number of rewiring lines, it is a matter of significant importance that these rewiring lines 27 between the contact pads 7 and the through contacts 11 can be made correspondingly narrow, which can be realized in particular by means of copper lines or nickel lines. While only the thirty-six through contacts 11 are evident toward the top side of the stacked module 14, which through contacts may, for their part, be covered with solderable coatings, correspondingly many external area contacts 2 are provided on the underside 12 in addition to the thirty-six through contacts 11, which area contacts may be arranged in a matrix with a uniform grid dimension r. The through contacts 11 may have a significantly smaller diameter than external area contacts 2, with the result that it is possible to realize a relatively compact electronic module 14 with corresponding through contacts.

FIGS. 8 to 23 illustrate schematic diagrams of the production of an electronic device 1 by means of a first exemplary implementation of the method according to the invention. Components in the subsequent FIGS. 8 to 23 which fulfill the same functions as in those in the previous figures are identified by the same reference symbols and are not discussed separately.

FIG. 8 illustrates a diagrammatic cross-sectional view of a carrier plate 26 with a patterned photoresist layer 17. The patterned photoresist layer 17 has openings 32 at the positions at which depressions or cutouts for external area contacts are intended to be introduced into the carrier 15 in a grid dimension r.

FIG. 9 illustrates a diagrammatic plan view of a carrier plate with a patterned photoresist layer 17. The in this case circular openings 32 in the photoresist layer 17 correspond to the dimensions of the cutouts to be produced for external area contacts of an electronic device in a predetermined grid dimension r. The arrows A-A denote the sectional planes in which the associated cross-sectional views of FIG. 8 and the following cross-sectional views are accommodated.

FIG. 10 illustrates a diagrammatic cross-sectional view of a carrier plate 26 with etched cutouts 16 for external area contacts of an electronic device. The cutouts 16 in the carrier plate 26 made of copper or a copper alloy are etched relatively shallow in this implementation method of the present invention. As carrier material for this first exemplary implementation of the method, iron or an iron alloy may also be provided as carrier material.

FIG. 11 illustrates a diagrammatic plan view of a carrier plate 26 with etched cutouts 16 for external area contacts. These cutouts are here only basically limited to nine cutouts and arranged in a matrix with a grid dimension r. The number of external area contacts may be increased as desired, however, as shown in FIG. 7.

FIG. 12 illustrates a diagrammatic cross-sectional view of a carrier plate 26 with a patterned photoresist layer 17 for selective deposition of a rewiring structure and for simultaneous selective deposition of external area contacts. A carrier plate 26 made of copper or a copper alloy that is prepared in this way has openings in the photoresist layer 17 which, on~the one hand, correspond to the geometry of the external area contacts 2 and, on the other hand, openings 32 corresponding to the rewiring structure 3 to be formed. The areal geometry is shown in the next figure.

FIG. 13 illustrates a diagrammatic plan view of a carrier plate with a patterned photoresist layer 17 for selective deposition of a rewiring structure and for selective deposition of external area contacts 2. For this purpose, depressions 16 which are already shown in FIG. 1 and are kept free of the photoresist layer 17 are illustrated in this structure, and structures for a rewiring 3 are additionally provided, which connect microscopically small contact areas of the semiconductor chip 4 to the macroscopically large areas of the external area contacts 2 which are intended to be formed in the cutouts 16.

FIG. 14 illustrates a diagrammatic cross-sectional view of a carrier plate 26 with a galvanically deposited rewiring structure 3 and with galvanically simultaneously deposited external area contacts 2 after the removal of the photoresist layer 17 shown in FIGS. 12 and 13. In the case of this exemplary implementation of the method according to the invention, both the external contact areas and the lines of the rewiring structure 3 are produced in a galvanic deposition step in which the metallic carrier 15 is connected to the cathode potential of a corresponding electrolyte bath. In this case, the insulation by the photoresist layer 17, as shown in FIG. 13, prevents the possibility of a large-area deposition of metal taking place on the carrier plate 26. Rather, a metal such as nickel, palladium, gold or silver is deposited in finely crystalline fashion with the thickness of the photoresist layer in the openings provided in the patterned photoresist 17 shown in FIG. 13.

FIG. 15 illustrates a diagrammatic plan view of a carrier plate 26 with a rewiring structure 3 deposited on the carrier plate 26 and with the external area contacts 2 after the removal of the photoresist layer 17 shown in FIG. 13. While only nine external contact areas 2 can be seen in this plan view, the number of external contact areas 2 can be increased as desired. In this embodiment of the invention, a central external contact area 2 is provided at the center of the structure, which is electrically connected to an outer external contact area 2 by means of a rewiring line 27. Such a central external area contact may be provided for example for the application of a ground potential, which can then also be offered on a further external area contact 2 by means of the rewiring line 27. Moreover, FIG. 11 shows the microscopically small contact pads 7 of each rewiring line, the size relationship illustrated here between microscopically small contact pads 7 and external area contacts 2 not being illustrated true to scale, especially as the contact pads 7 may have a size of only a few square micrometers, while the external contact areas have a size of up to a few hundred square micrometers.

FIG. 16 illustrates a diagrammatic cross-sectional view of a carrier plate 26 with an applied semiconductor chip 4. In this embodiment of the invention, the semiconductor chip 4 is connected to the contact pads 7 of the rewiring structure 3 by means of internal area contacts 28 using flip-chip technology. For this purpose, the internal area contacts 28 may have materials that enable diffusion soldering on the rewiring structure 3. Intermetallic phase transitions arise during the diffusion soldering and ensure an extremely stable electrical connection between the contact areas of the semiconductor chip 4 and the contact pads 7 of the rewiring plate via the internal area contacts 28.

FIG. 17 illustrates a diagrammatic plan view of a carrier plate 26 with an applied semiconductor chip 4. In this plan view, said semiconductor chip 4 can be seen from the rear side 8, for which reason the microscopically small contact areas 5 and the associated contact pads 7 of the rewiring structure 3 are illustrated by broken lines. The contact pads 7 are laid outward in a so-called “fan-out” arrangement, since the base area of the semiconductor chip 4 does not suffice to accommodate the macroscopic external area contacts in the region. Consequently, the external area contacts 2 are visible in this embodiment of the invention and the illustration of FIG. 17. Only short rewiring line sections 27 of the rewiring structure 3 are discernable, since the rest of the rewiring structure is covered by the semiconductor chip 4.

FIG. 18 illustrates a diagrammatic cross-sectional view of a carrier plate 26 provided with plastic housing composition 6. During the application of the plastic housing composition 6, both the semiconductor 4 and the rewiring structure 3 are completely embedded in plastic housing composition; only the boundary transition to the metallic carrier plate 26 remains and is not enclosed by plastic housing composition 6.

FIG. 19 illustrates a diagrammatic plan view of a carrier plate provided with plastic housing composition 6, so that the top side 13 of the electronic device constitutes a non-patterned smooth surface comprising plastic housing composition 6. However, the electronic device arranged in the plastic housing composition is not yet functional since the metallic carrier plate 26 short-circuits all external area conductors and parts of the rewiring structure. This short-circuit is eliminated by etching away the metallic carrier plate 26, which is provided as a sacrificial plate and, in this exemplary implementation of the invention, comprises a carrier material a, which differs from the galvanically deposited material b of the external area contacts and the rewiring structure, as far as the interface between the materials a and b, or the interface between the material a and the plastic housing composition 6. For this purpose, the structure shown in FIG. 18 may be dipped into a corresponding etching bath. By virtue of the difference in etching rates for copper or copper alloys or nickel and nickel alloys as materials a and b, the etching process can be ended relatively precisely upon reaching the transition region between copper and nickel.

FIG. 20 illustrates a diagrammatic cross-sectional view of an electronic device 1 after the removal of the carrier material from the device 1, so that now the external area contacts and also the rewiring structure are uncovered at least on one side and can be accessed externally.

FIG. 21 illustrates a diagrammatic bottom view of an electronic device 1 after the removal of the metallic carrier from the device 1. Both the external area contacts 2 and the rewiring structure with its contact pads 7 are initially arranged in uncovered fashion on the underside 12 of the electronic device. By fitting a patterned soldering resist layer, however, it is possible for the rewiring regions to be covered and only the external area contacts 2 to remain uncovered.

FIG. 22 illustrates a diagrammatic cross-sectional view of an electronic device 1 after the application of the soldering resist mask 18. This soldering resist mask 18 is applied to the underside of the electronic device in order to protect the rewiring structure 3 and at the same time to limit the possibility of fitting solder balls on the external area contacts to the latter themselves and to prevent the material from flowing along the rewiring lines of the rewiring pattern 3.

FIG. 23 illustrates a diagrammatic bottom view of an electronic device 1 after the application of a soldering resist layer 18. It is still possible to see, in part, the plastic housing composition 6 in the uncovered areas of the external area contacts, since the openings in the soldering resist layer have been chosen to be somewhat larger than the diameters of the external area contacts 2.

In a method for producing an electronic device that is not illustrated here, use is made of a carrier sheet with embossed cutouts for external area contacts. The sheet may be a sheet that is surface-activated for chemical depositions or, for galvanic depositions, be an electrically conductive sheet or a sheet coated with a conductive substance such as graphite or metal. The advantage of a production method based on a carrier sheet is that etching-away of the carrier plate of the first exemplary implementation is obviated and, after the completion of the electronic device, the sheet merely has to be stripped away or dissolved from the underside of the device.

The further advantage of a method based on a carrier sheet is that the sheet material and thus the material of the carrier has fundamentally different properties than the material of the area contacts, which have a chemically or galvanically deposited metal in accordance with the present invention. Consequently, copper may also be used directly as material of the area contact. Furthermore, the layer sequences gold copper gold or palladium copper gold or nickel copper gold can be produced without any problems, since an etching step is obviated when using a carrier sheet 21.

As in the case of a method based on a carrier plate preferably made of copper, iron or alloys thereof, in this case also the cutouts are arranged in a predetermined grid dimension, which corresponds to the grid dimension of a superordinate circuit, for example on a printed circuit board, in order to electrically connect the electronic device to a superordinate circuit.

In contrast to the method shown in FIGS. 8 to 23, the entire carrier sheet is covered with a first photoresist layer whilst leaving free the cutouts, which layer is intended to prevent a deposition of area contact material on the areas of the carrier sheet that are protected by the photoresist layer, so that only the material of the area contacts is deposited in the cutouts.

From this process step the method proceeds further as in the case of the method described above.

In contrast to the etching technology which is illustrated in the first example for a method for producing an electronic device 1 and is shown in FIGS. 8 to 23, in this case, after the removal of the mold shown in the previous figures, the sheet can be stripped away from the underside of the electronic device or can be dissolved in a corresponding solution without damaging in the process the rewiring structure embedded in the plastic housing composition and the external area contacts projecting from the plastic housing composition. In principle, the electronic device is then completely produced and, compared with other technologies, has an extremely small device height of less than 400 micrometers, preferably between 250 and 300 micrometers. This device height can be minimized further if the semiconductor chip is thinned to thicknesses d of less than 100 micrometers prior to installation.

In a further method (not shown here) for producing an electronic device by means of a third exemplary embodiment of the method according to the invention, the starting point is once again a carrier made of a metal or a carrier plate which is provided at least with a metal layer. In addition to the cutouts for external area contacts, provision is made of further cutouts for external area contacts of through contacts to be realized. In this case, one group of cutouts may differ in size from the other cutouts in such a way that, by way of example, their diameter is smaller. The smaller diameter of the other cutouts ensures that the later through contacts through the housing of the electronic device have a smaller diameter and thus also take up a smaller space of the electronic device.

As a result, embossed cutouts that are used in this third exemplary embodiment of the method do not differ in any way from the etched cutouts 16 as were used in the first method. However, the embossing may be more cost-effective since these cutouts can be introduced by an embossing roll, while etching usually involves providing a photoresist layer that has to be correspondingly patterned.

The number of additional area contacts is in each case four on both sides in this exemplary implementation of the method and they correspond to eight contact areas (which cannot be seen) of a semiconductor chip such as is already shown in the first two exemplary embodiments. In this plan view, the ninth central contact is short-circuited with one of the contacts arranged at the edge by means of a rewiring line and therefore does not need a separate through contact at the edge of the electronic device.

FIG. 24 illustrates a diagrammatic cross-sectional view of a carrier plate 26 with a patterned first photoresist layer 19 for selective deposition of external area contacts in the cutouts 16 and 23 provided therefor. For this purpose, the first photoresist layer 19 is applied to the carrier 15 and the regions in which area contacts are provided are developed out.

FIG. 25 illustrates a diagrammatic plan view of a carrier plate 26 with a first photoresist layer 19 for selective deposition of external area contacts. FIG. 25 differs from FIG. 23 merely by the fact that now the top side of the carrier 15, as is shown in FIG. 24, is covered with the first photoresist layer 19 and only the cutouts 16 and 23 are left free for deposition of the external area contacts.

FIG. 26 illustrates a diagrammatic cross-sectional view of a carrier plate 26 with galvanically deposited external area contacts 2 after the removal of the first photoresist layer. The cutouts, which could still be seen in FIGS. 24 and 25 are now completely filled with a chemically or galvanically deposited metal and the top side of the carrier 15 is free for receiving a further patterned photoresist layer.

FIG. 27 illustrates a diagrammatic plan view of a carrier plate 26 with external area contacts 2 deposited on the carrier plate 26. The material of the area contacts 2 both in the cutouts for external area contacts 2 and in the cutouts for area contacts 2 with subsequent through contacts is completely identical as a result of the common deposition process. It goes without saying that, by splitting up with further photoresist layers, it is possible to deposit different material for the cutouts 23 and the cutouts 16. This is not provided in this exemplary embodiment of the invention, however, especially as each additional photoresist step or photolithography step increases the process costs.

FIG. 28 illustrates a diagrammatic cross-sectional view of a carrier plate 26 with a patterned second photoresist layer 20 for selective deposition of a rewiring structure. In a manner similar to that in the case of the second exemplary implementation of the method, the materials of the rewiring structure and of the external area contacts 2 can be chosen to be different in this case, since in this case two separate photoresist steps with a respective photoresist mask are provided for the deposition of the external area contacts 2 and for the deposition of the rewiring structure. Furthermore, the thickness of the external area contacts 2 may differ significantly from the thickness of the rewiring structure 3 since, in this third exemplary implementation, in a similar manner to that in the case of the second exemplary implementation, two photoresist steps 19 and 20 are provided for patterning rewiring structure 3 and external area contacts 2.

FIG. 29 illustrates a diagrammatic plan view of a carrier plate with a second patterned photoresist layer 20 for selective deposition of the rewiring structure 3. This rewiring structure 3 is provided not only in the regions of the rewiring lines 27 but also on the already deposited area contacts 2. For each of the area contacts 2, provision is made of an area contact located at the edge and having smaller dimensions, which is connected to through contacts in the further course of the method.

FIG. 30 illustrates a diagrammatic cross-sectional view of a carrier plate 26 with a galvanically deposited rewiring structure 3 and the external area contacts 2 already deposited beforehand after the removal of the second patterned photoresist layer 20 shown in FIGS. 28 and 29. With the removal of the second photoresist layer, the rewiring structure 3 on the carrier plate 26 is uncovered and is accessible for further method steps.

FIG. 31 illustrates a diagrammatic plan view of a carrier plate 26 with a rewiring structure 3 deposited on the carrier plate 26 after the removal of the photoresist layer. This rewiring structure 3 is already somewhat more complicated than in the first two exemplary implementations of the method since not only do macroscopic external contact areas 33 of the rewiring structure 3 cover the external area contacts 2, but rewiring lines 27 lead to the microscopically small contact pads 7 and to the smaller area contacts 23 of the through contacts to be deposited.

FIG. 32 illustrates a diagrammatic cross-sectional view of a carrier plate 26 with a patterned further photoresist layer 24 for selective deposition of through contacts. The thickness D of the photoresist layer 24 corresponds to the future thickness of the plastic housing composition and has openings 25 aligned with the additional external area contacts 2 for the future through contacts. With special photoresists and special exposure devices, it is possible to achieve a photoresist thickness D of up to 1 mm and at the same time it is possible to realize openings 25 with relatively perpendicular walls, in particular by means of the so-called projection exposure of a photoresist having a corresponding thickness. However, only a thickness of up to 400 micrometers is provided for the devices according to the invention, so that the production of openings 25 with relatively perpendicular walls is unproblematic.

Through the further patterned photoresist layer, an additional structure comprising through contacts is now attained on the already produced rewiring structure 3 by deposition on the previous structure or by filling the openings 25 with corresponding metal material.

FIG. 33 illustrates a diagrammatic plan view of a carrier plate with a further patterned photoresist layer 24 for selective deposition of through contacts. This plan view is only diagrammatic insofar as the course of the rewiring lines and of the area contacts for the connection to the contact areas of a semiconductor chip can also be seen, which, however, are covered by the further patterned photoresist layer with openings 25 for through contacts.

FIG. 34 illustrates a diagrammatic cross-sectional view of a carrier plate 26 with galvanically deposited through contacts 11 after the removal of the further photoresist layer 24 which is illustrated in FIGS. 32 and 33. In principle, FIG. 34 provides a metallic frame for a future electronic device since all electrically conductive components, whether through contacts 11, external area contacts 2 and rewiring lines 27, contact pads 7 and external contact areas 33 are now embodied and are held together and supported by the carrier 15.

FIG. 35 illustrates a diagrammatic plan view of a carrier plate 26 with through contacts deposited on the carrier plate 26 and the rewiring structure 3 and also the position of contact pads 7 and external area contacts 2 after the removal of the further photoresist layer 24 shown in FIGS. 32 and 33. As can be seen from FIG. 35, at the center a sufficient area remains free between the through contacts in order to position a semiconductor chip.

The semiconductor chip 4 is then applied using flip-chip technology as has already been shown in the previous exemplary implementations of the method. In this case, the height of the through contacts 11 is greater than the height of the semiconductor chip 4, so that, during the subsequent application of a plastic housing composition, the semiconductor chip 4 with the rewiring structure 3 can be completely embedded in plastic housing composition.

FIG. 36 illustrates a diagrammatic cross-sectional view of a carrier plate 26 provided with plastic housing composition 6, in which case, as a result of the application of the plastic housing composition 6, the semiconductor chip 4 and the rewiring structure 3 and also the through contacts 11 are completely embedded in a plastic housing composition 6, but the through contacts 11 are uncovered on the top side of the electronic device since the height or thickness of the through contacts 11 corresponds to the thickness D of the plastic housing composition 6. The undersides of the rewiring structure and the undersides of the external area contacts also remain free of plastic housing composition 6 since they are protected by the carrier plate 26. In this case, the carrier plate 26 may simultaneously serve as a mold during the injection-molding of the plastic housing composition 6. On the other hand, the metallic carrier plate 26 short-circuits the external area contacts 2 and the rewiring structure 3, so that the electronic device can neither be tested nor is it functional.

FIG. 37 illustrates a diagrammatic plan view of a carrier plate provided with plastic housing composition. In this plan view, the through contacts 11 are uncovered at the top side 13 of the electronic device 1 and can thus be contact-connected by a superordinate circuit board or by an identical electronic device.

After the removal of the carrier 15 from the electronic device 1, the external area contacts 2 are freely accessible and the through contacts can be electrically connected both on the underside and on the top side, but the rewiring structure is freely accessible from its underside, which means there is a risk of damage to the relatively sensitive rewiring lines. The metallic carrier plate is removed by means of etching technology, the material difference between the carrier material a shown in FIG. 36 and the material b of the external area contacts 2 and the rewiring structure 3 ensuring an etching stop.

After the removal of the carrier 15 from the device 1, all metallic areas of the underside of the electronic device would be accessible. For the rewiring lines 27, this has the disadvantage, however, that, for example during soldering connection to a higher circuit arrangement, they would be exposed to the flowing-on of soldering tin.

FIG. 38 illustrates a diagrammatic cross-sectional view of an electronic device 1 after the application of a soldering resist layer 18. This soldering resist layer 18 is applied to the entire underside 12 of the electronic device 1. In this case, it is particularly important that the soldering resist layer covers in particular the rewiring structure 3 apart from the external area contacts 2. Consequently, the external area contacts 2 both for the through contacts 11 and for the external area contacts which are connected to the contact areas 5 of the semiconductor chip 4 by means of the rewiring structure 3 remain freely accessible.

FIG. 39 illustrates a diagrammatic bottom view of an electronic device 1 after the application of a soldering resist layer 18. This soldering resist layer 18 may be arranged in such a way that it still leaves free a small edge all around each external area contact 2, so that the plastic housing composition 6 becomes visible at these locations.

An electronic device 1 produced by means of the third exemplary embodiment of the method has the advantage that via through contacts 11, electronic devices 1 of identical type can now be stacked vertically in any desired number in order to produce highly complex and extremely dense electronic modules 14 as shown in FIGS. 4 to 7.

What is claimed is:

1-31. (canceled)

32. An electronic device comprising:
external area contacts;
a rewiring structure;
a semiconductor chip, which has contact areas, the external area contacts being electrically connected to the contact areas at least by means of the rewiring structure; and
wherein the semiconductor chip and the rewiring structure are embedded in a plastic housing composition, and the external area contacts and the rewiring structure have chemically or galvanically selectively deposited metal.

33. The electronic device of claim 31, where the semiconductor chip is mounted on the rewiring structure using flip-chip technology, and the contact areas of the semiconductor chip are electrically connected to contact pads of the rewiring structure by inner area contacts.

34. The electronic device of claim 31, comprising the semiconductor chip is mounted by its rear side on the rewiring structure and the contact areas on the active top side of the semiconductor chip are connected to contact pads of the rewiring structure by bonding wires.

35. The electronic device of claim 31, comprising the electronic device having, on the rewiring structure, chemically or galvanically selectively deposited through contacts that extend from the underside of the electronic device as far as an opposite top side of the electronic device, the underside of the electronic device having external area contacts.

36. The electronic device of claim 35, comprising the through contacts surrounding the semiconductor chip and are embedded in the plastic housing composition.

37. The electronic device of claim 35, comprising a plurality of individual electronic devices are stacked vertically one above the other and are electrically connected to one another by means of the through contacts.

38. The electronic device of claim 31, wherein the chemically or galvanically deposited metal comprises nickel or a nickel alloy.

39. The electronic device of claim 31, wherein the chemically or galvanically deposited metal comprises silver or a silver alloy, copper or a copper alloy, gold or a gold alloy, or palladium or a palladium alloy.

40. The electronic device of claim 31, where the chemically or galvanically deposited metal includes a layer sequence comprising gold nickel gold.

41. The electronic device of claim 31, where the chemically or galvanically deposited metal includes a layer sequence comprising palladium nickel palladium.

42. The electronic device of claim 31, where the chemically or galvanically deposited metal includes a layer sequence comprising palladium copper palladium.

43. The electronic device of claim 31, where the chemically or galvanically deposited metal includes a layer sequence comprising gold copper gold.

44. An electronic device comprising:
external area contacts;
a rewiring structure;
a semiconductor chip, which has contact areas, the external area contacts being electrically connected to the contact areas at least by means of the rewiring structure;
wherein the semiconductor chip and the rewiring structure are embedded in a plastic housing composition, and the external area contacts and the rewiring structure have chemically or galvanically selectively deposited metal, and where the semiconductor chip is mounted on the rewiring structure using flip-chip technology, and the contact areas of the semiconductor chip are electrically connected to contact pads of the rewiring structure by inner area contacts, and wherein the semiconductor chip is mounted by its rear side on the rewiring structure and the contact areas on the active top side of the semiconductor chip are connected to contact pads of the rewiring structure by bonding wires; and
the electronic device having, on the rewiring structure, chemically or galvanically selectively deposited through contacts that extend from the underside of the electronic device as far as an opposite top side of the electronic device, the underside of the electronic device having external area contacts.

45. The electronic device of claim 44, comprising the through contacts surrounding the semiconductor chip and are embedded in the plastic housing composition.

46. The electronic device of claim 45, comprising a plurality of individual electronic devices are stacked vertically one above the other and are electrically connected to one another by means of the through contacts.

47. A method for producing an electronic device having external area contacts and having a rewiring structure, the external area contacts and the rewiring structure comprising chemically or galvanically selectively deposited metal, and the method comprising:
producting an electrically conductive carrier, having cutouts in a predetermined grid dimension for a chemical or galvanic deposition of the external area contacts of the electronic device, different materials being used for the external area contacts and for the top side of the carrier;
applying a patterned photoresist layer to the carrier whilst leaving free the cutouts for the external area contacts and for regions in which the rewiring structure is to be chemically or galvanically deposited;
chemical or galvanic depositing of a material, which differs from the material of the carrier, in the cutouts and in the regions of the rewiring structure;
removing the photoresist layer;
applying a semiconductor chip to the rewiring structure whilst connecting the contact areas of the semiconductor chip to contact pads of the rewiring structure;
embedding the semiconductor chip and the rewiring structure in a plastic housing composition;
separating the carrier from the encapsulated device whilst uncovering the external area contacts;
applying a soldering resist layer on the device side of the area contacts whilst leaving free the area contacts.

48. The method of claim 47, comprising:
applying firstly a first photoresist layer on the carrier, the photoresist layer leaving free the cutouts for the external area contacts, the cutouts are filled with area contact material by chemical or galvanic deposition; and
applying afterward a second photoresist layer, which leaves free the regions of the rewiring structure in which the rewiring structure is subsequently chemically or galvanically deposited.

49. The method of claim 47, comprising using an electrically conductive sheet as carrier, into which sheet are embossed cutouts for forming area contacts of the electronic device.

50. The method of claims 47, comprising using a nonconductive carrier material, on which a conductive layer is deposited, for the carrier.

51. The method of claims 47, comprising mechanically supporting, during the embedding of the device in a plastic housing composition, a carrier made of a sheet, by an adapted mold.

52. The method of claim 47, comprising providing additional cutouts for external area contacts of through contacts in the carrier.

53. The method of claim 47, comprising further applying a patterned photoresist layer, after completion and deposition of the area contacts and of the rewiring structure, to the carrier with a thickness greater than the thickness of the semiconductor chip whilst leaving free the area contacts for the through contacts, the further photoresist layer having openings that are subsequently filled chemically or galvanically to form through contacts.

54. The method of claim 47, comprising, in order to produce the cutouts in the conductive carrier, covering the carrier with a patterned photoresist layer whilst leaving free the regions for the cutouts and cutouts are subsequently etched into these regions.

55. The method of claim 47, comprising embossing the cutouts into the carrier.

56. The method of claim 47, comprising mounting the semiconductor chip on the rewiring structure using flip-chip technology by the contact areas of the semiconductor chip being connected to corresponding contact pads of the rewiring structure.

57. The method of claim 47, comprising adhesively bonding the semiconductor chip by its rear side on the rewiring structure, and connecting its contact areas to contact pads of the rewiring structure via bonding wires.

58. The method of claim 47, comprising effecting the embedding of the components in a plastic housing composition in the cavity of a mold by injecting molding technology.

59. The method of claim 47, comprising effecting the embedding of the components in a plastic housing composition by a dispensing method.

60. The method of claim 47, comprising effecting the separation of the carrier from the device by etching technology, the etching process stopping at the boundary line between the material of the carrier and the material of the area contacts.

61. The method of claim 47, comprising effecting the separation of the carrier from the device by stripping away a sheet.

62. The method of claim 47, comprising providing the one carrier in wafer form for a simultaneous production of a multiplicity of electronic devices firstly with cutouts, and in that afterward all of the method steps are carried out jointly for production for the multiplicity of electronic devices and finally, after removal of the carrier in wafer form, the multiplicity of electronic devices that are packaged in a plastic housing composition are separated by division of the plastic housing composition to form a multiplicity of electronic devices.

63. An electronic device comprising:
external area contacts;
a rewiring structure;
a semiconductor chip having contact areas;
means for electrically connecting the external area contacts to the contact areas at least by the rewiring structure; and
wherein the semiconductor chip and the rewiring structure are embedded in a plastic housing composition, and the external area contacts and the rewiring structure have chemically or galvanically selectively deposited metal.

64. The electronic device of claim 63, where the semiconductor chip is mounted on the rewiring structure using flip-chip technology, and the contact areas of the semiconductor chip are electrically connected to contact pads of the rewiring structure by inner area contacts.
